(19) United States
(12) Patent Application Publication
(10) Pub. No.: US 2010/0132756 A1
(43) Pub. Date: Jun. 3, 2010

(54) VISIBLE-LIGHT TRANSMITTING SOLAR-HEAT REFLECTIVE FILM

(76) Inventors: Kazuhiko Tonooka, Ibaraki (JP); Naoto Kikuchi, Ibaraki (JP)

Correspondence Address: KENYON & KENYON LLP, ONE BROADWAY, NEW YORK, NY, 10004, US

(21) Appl. No.: 12/451,960

(22) PCT Filed: May 21, 2008
(86) PCT No.: PCT/JP2008/059331

§ 371 Date: Dec. 8, 2009

(30) Foreign Application Priority Data
Jun. 11, 2007 (JP) 2007-153928

(51) Int. Cl. H01L 35/30; H01L 31/052; G02B 5/28

(52) U.S. Cl. 136/242; 136/246; 359/359

(57) ABSTRACT

It is intended to realize a sheet which is used as a windshield of a building, a vehicle or a house or adhered to window glass, so that it may reflect and shield solar radiation heat rays, which might otherwise become a thermal load on air conditioning, while retaining natural illumination from solar radiation, thereby to have such functions to transmit the visible light and to reflect the heat rays are effective for saving the energy. Provided is a visible light transmitting solar-heat reflecting film, which is made of a multi-layered film including at least one layer of a high refractive index material formed in an optically transparent base material and having a refractive index of 2.0 to 2.6 and a thickness of 10 to 325 nm, and at least one layer of a low refractive index material having a refractive index of 1.8 or less and a thickness of 10 to 325 nm. The solar-heat reflecting film has an average optical transmittance of 60% or more to a light of a wavelength of 400 to 700 nm, and sacrifices the reflectivities of wavelengths near 1115 nm and 1385 nm, at which the energy density on the earth surface is the minimum, due to the absorptions by the water vapor of the atmosphere in the heat ray contained in the solar radiation, thereby improving the average reflectivity for the heat ray of a wavelength of 800 to 1040 nm of a relatively high energy density, to 80% or more, and the average reflectivity for the heat ray of a wavelength of 1150 to 1300 nm, to 50% or more.

### TECHNICAL FIELD

The present invention relates to a solar-heat reflective film effective for energy saving, which is used as a window for buildings, houses or vehicles or adhered to a windowpane, etc. and can shield strong infrared rays while ensuring natural lighting from solar radiation.

### BACKGROUND ART

In recent years, with a growing interest in energy saving, a need for technology of ensuring sunshine while avoiding solar-heat that is a main cause of the cooling load is increasing. In other words, there is a demand for effective energy saving of windows of buildings, vehicles, houses, etc., which ensures natural lighting from solar light (sunshine) and, at the same time, prevents transmission of infrared light not contributing to brightness perceived by the human eye.

According to the Energy-Saving Standard (standard of 1992), 71% of heat flowing into a building enters through windows during summer daytime hours which requires air conditioning. The source of the inflowing heat is solar radiation and since about 50% of solar radiation energy produces a heat effect without contributing to the brightness perceived by the human eye, therefore the solar-heat reflection is very effective for energy saving of buildings.

Conventionally, the technology of reflecting light at undesired wavelengths while ensuring high transmittance of light at desired wavelengths is roughly classified into three groups, i.e., an optical multilayer film, plasma reflection, and a metal thin film.

For example, an ultraviolet/infrared ray shielding glass coated with an ultraviolet absorbing substance-containing optical multilayer film composed of titanium oxide, cerium oxide and zinc oxide is known (see, Patent Document 1). Also, a production method of an ultraviolet-ray absorbing heat-ray reflective glass coated with an optical multilayer film composed of titanium oxide, cerium oxide and bismuth oxide is known (see, Patent Document 2).

Furthermore, a production method for stacking a heat-ray reflective film utilizing plasma reflection of electroconductive fine particles (see, Patent Document 3), and an ultraviolet and heat rays window having a structure where a film absorbs ultraviolet rays and a metal or metal nitride film that reflects heat rays (see, Patent Document 4) and known.

Patent Document 1: Kokai (Japanese Unexamined Patent Publication) No. 09-278492

Patent Document 2: Kokai No. 10-236847

Patent Document 3: Kokai No. 2000-72484

Patent Document 4: Kokai No. 07-138049

### DISCLOSURE OF THE INVENTION

### Problems to be Solved by the Invention

The conventional technique of heat ray reflection by plasma reflection is in principle useful for heat-ray reflection on the long wavelength side and is improper for heat-ray reflection on the short wavelength side. Regarding solar radiation heat rays, the energy density is larger on the shorter wavelength side and a high solar-heat shielding effect cannot be easily obtained by utilizing plasma reflection.

The technique of heat ray reflection by a metal thin film enables easily of high reflectance, but the reflection is relatively flat with respect to wavelength and therefore, the visible light transmittance needs to be sacrificed to realize high reflectance for heat ray.

In addition, the heat-ray reflective film having introduced thereinto an electroconductive material such as metal can reflect an electromagnetic wave, which prevents utilization of a cellular phone, ETC, etc., which are being widely used.

The heat ray reflection with an optical multilayer film tends to cost more than plasma reflection or a metal thin film, but it is expected that both high visible light transmittance and effective heat ray reflection can be obtained by making use of high transmittance and steep transition of an optical multilayer film.

Taking into consideration these problems in the conventional techniques, the present invention aims at realizing a visible-light transmitting solar-heat reflective film having an electromagnetic wave transmitting function by making use of a steep transition as an advantage of an optical multilayer film, with a main focus on greatly improving the energy saving effect by solar heat reflection than in the conventional techniques, when used as a windowpane.

That is, an object of the present invention is to obtain a film capable of effectively reflecting undesired heat rays contained in solar radiation while transmitting visible light. It is reported that the solar radiation has a spectral property as shown in FIG. 1. As a noteworthy property of the solar heat rays, the heat rays on the short wavelength side have high energy density, and the energy level decreases as the wavelength becomes longer. The solar heat enters into a building in the form of light, and therefore in order to eliminate solar heat, it is necessary to reflect the high energy density portion of the heat ray.

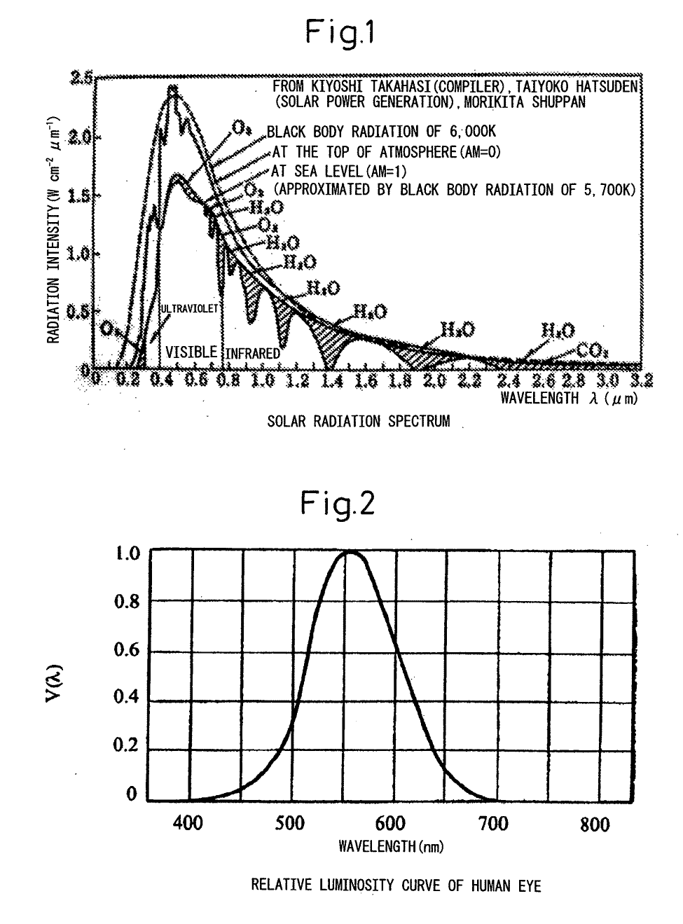

Regarding visible-light transmission, the characteristics thereof need to be harmonized with the spectral luminous efficiency (photopic vision) of the human eye as shown in FIG. 2. According to FIG. 2, transmitting light at a wavelength of 400 to 700 nm is considered to be appropriate for visible-light transmission. However, an ideal visible-light transmitting solar-heat reflective film is necessary to reflect all heat rays at a wavelength of 700 nm or more while transmitting light at a wavelength of 400 to 700 nm.

However, in conventional optical multilayer film technology, even when it is intended to transmit light in the visible-light region at as evenly and high a transmittance as possible, and at the same time, reflect a heat ray of about 700 nm or more at as high a reflectance as possible up to a longer wavelength, the reflectance is known to rapidly decrease at a wavelength of 1,050 nm or more. Therefore, conventional optical multilayer film technology cannot easily satisfy the above-described two requirements in terms of visible-light transmittance and heat reflection.

### Means to Solve the Problems

The present inventor studied the solar radiation spectrum (FIG. 1) in detail, and intended to achieve effective heat reflection by utilizing the property thereof. According to FIG. 1, almost 90% of the solar radiation energy exists in the range from ultraviolet ray to a wavelength of about 1,400 nm (=1.4 μm) and therefore, the inventor attempted to preferentially reflect the heat rays in this range to effectively eliminate solar heat.

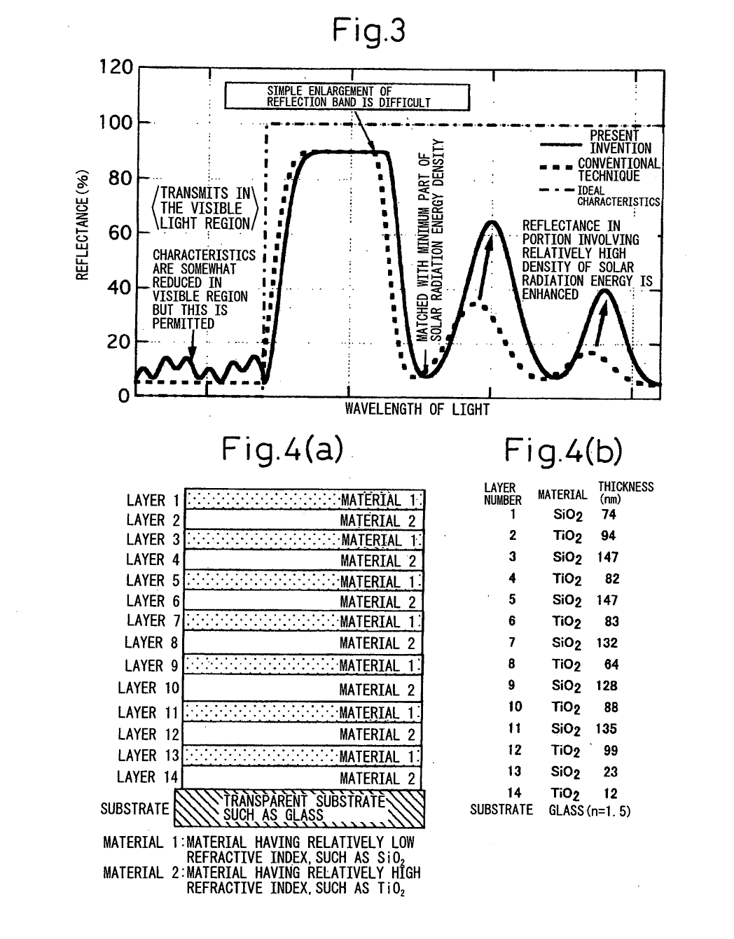

More specifically, partial reduction of reflectance for the solar-heat is permitted as shown by the solid line in FIG. 3, whereby reflectance in the portion important for the elimination of solar-heat is enhanced. First, the fundamental technical idea set is to sacrifice the reflectance in the vicinity of wavelengths of 1,115 nm and 1,385 nm where the energy density of solar radiation is minimum due to absorption by water vapor, etc., in the atmosphere, and thereby raise the reflectance in the wavelength region involving a higher energy density than the energy density at the above wavelengths.

Next, some reduction of transmittance in the visible light region is also permitted to raise the reflectance for heat rays. The visible light transmittance of an optical multilayer film originally has a high value of about 90% and therefore, by adopting the above-described means to solve the problems, the total energy amount of reflected heat rays can be increased while maintaining a visible-light transmittance high enough to allow use as a windowpane or the like. Judging from the solar radiation spectrum shown in FIG. 1, “the vicinity of a wavelength of 1,115 nm” as used herein is suitably from 1,080 to 1,150 nm. Similarly, “the vicinity of a wavelength of 1,385 nm” is suitably from 1,330 to 1450 nm.

In summary, the present invention is a visible-light transmitting solar-heat reflective film formed on a light-transparent substrate, comprising a multilayer film containing one or more layers of a high refractive index material having a refractive index of 2.0 to 2.6 and a thickness of 10 to 325 nm and one or more layers of a low refractive index material having a refractive index of 1.8 or less and a thickness of 10 to 325 nm, wherein the average transmittance for light at a wavelength of 400 to 700 nm is 60% or more; and the reflectance in the vicinity of wavelengths of 1,115 nm and 1,385 nm, where the energy density on the earth's surface is minimum in the heat rays contained in solar radiation due to absorption by water vapor and others in the atmosphere, is sacrificed so as to raise the average reflectance for heat rays at a wavelength of 800 to 1,040 nm involving a high energy density to 80% or more and similarly raise the average reflectance for heat rays at a wavelength of 1,150 to 1,300 nm to 50% or more.

The high refractive index material layer is preferably formed of a material comprising, as the main component, a metal oxide composed of one member or two or more members selected from the group consisting of titanium, indium, tin, zinc, cerium, bismuth, zirconium, niobium and tantalum.

The low refractive index material is preferably composed of a material comprising, as the main component, a fluoride of calcium, barium, lithium or magnesium, or silica.

The light-transparent substrate which can be used includes a silicate- or borate-based glass, and a plastic such as polycarbonate and polyethylene terephthalate. The visible-light transmitting solar-heat reflective film of the present invention can be utilized as a windowpane when formed on a glass substrate and can be utilized as a visible-light transmitting solar-heat reflective sheet when formed on a plastic sheet substrate.

Also, the present invention is a visible-light transmitting solar-heat reflective film formed on a light-transparent substrate, comprising a multilayer film containing one or more layers of a high refractive index material having a refractive index of 2.0 to 2.6 and a thickness of 10 to 325 nm and one or more layers of a low refractive index material having a refractive index of 1.8 or less and a thickness of 10 to 325 nm, wherein the attenuation for an electromagnetic wave at a wavelength of 800 MHz to 2.4 GHz is 2 dB or less; the average transmittance for light at a wavelength of 400 to 700 nm is 60% or more; and the reflectance in the vicinity of wavelengths of 1,115 nm and 1,385 nm, where the energy density on the earth's surface is minimum in the heat rays contained in solar radiation due to absorption by water vapor, etc., in the atmosphere, is sacrificed so as to raise the average reflectance for heat rays at a wavelength of 800 to 1,040 nm involving a relatively high energy density to 80% or more and raise the average reflectance for heat rays at a wavelength of 1,150 to 1,300 nm to 50% or more.

### Effects of the Invention

The visible-light transmitting solar-heat reflective film of the present invention produces the following notable effects.

(1) The functional film of the present invention can be utilized like a windowpane by forming it on a transparent glass plate or plastic plate and thanks to reflection of solar-heat, contributes to saving power consumption in air conditioning. Statistics reveal that the power demand yields a peak in temperate regions due to air conditioning in summer. According to estimates in the Energy-Saving Standard (standard of 1992), 71% of the quantity of heat intruding into a building is supposed to enter through a window during the summer daytime hours requiring air conditioning. Since about half of the heat enters as a heat ray contained in the solar radiation, it is understood that heat ray reflection produced by the present invention is effective in reducing the cooling load and saving the energy.

(2) In the present invention, transmission of visible light and reflection of heat rays are realized by using a material having high transmittance for light and therefore, light absorption and heat generation associated therewith can be greatly reduced.

(3) By forming the functional thin film of the present invention on a plastic sheet and laminating the film/sheet on a windowpane or the like, a function of reflecting heat rays without shielding natural lighting or hindering vision can be easily added. That is, an energy saving function can be effectively added even to an existing windowpane.

(4) The visible-light transmitting solar-heat reflective film of the present invention has a function of separating the solar radiation into visible light and heat rays, so that not only visible light can be utilized for natural indoor lighting but also heat rays separated from solar radiation can be utilized for power generation and the like. According to the present invention, heat rays on the longer wavelength side than a wavelength of about 750 nm can be separated, so that by supplying the heat rays as energy for power generation to a solar cell or the like, a visible-light transmitting solar power generating function can be easily realized.

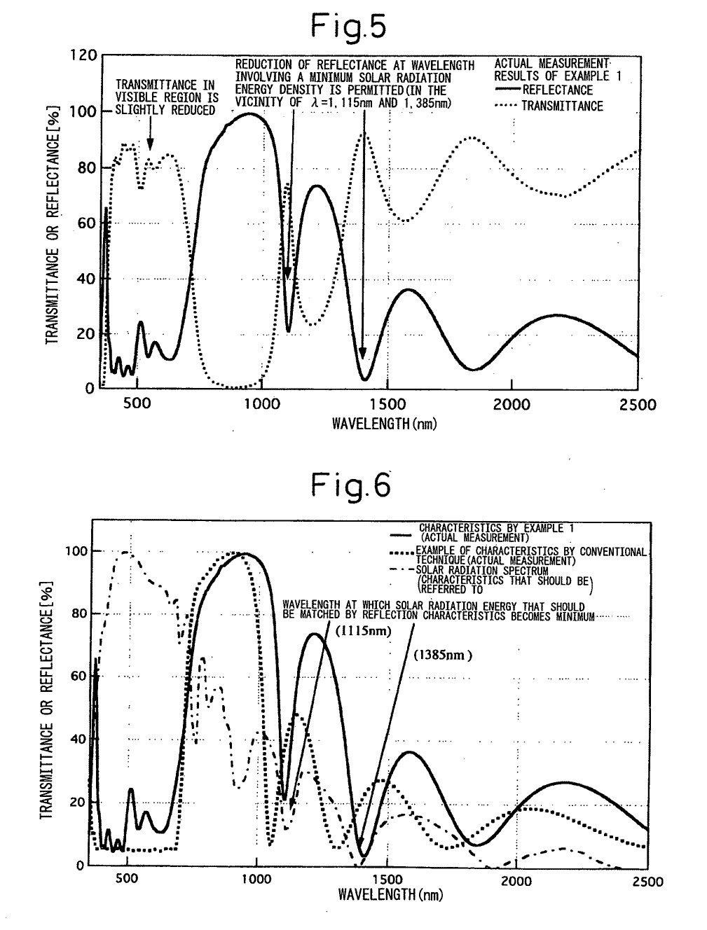

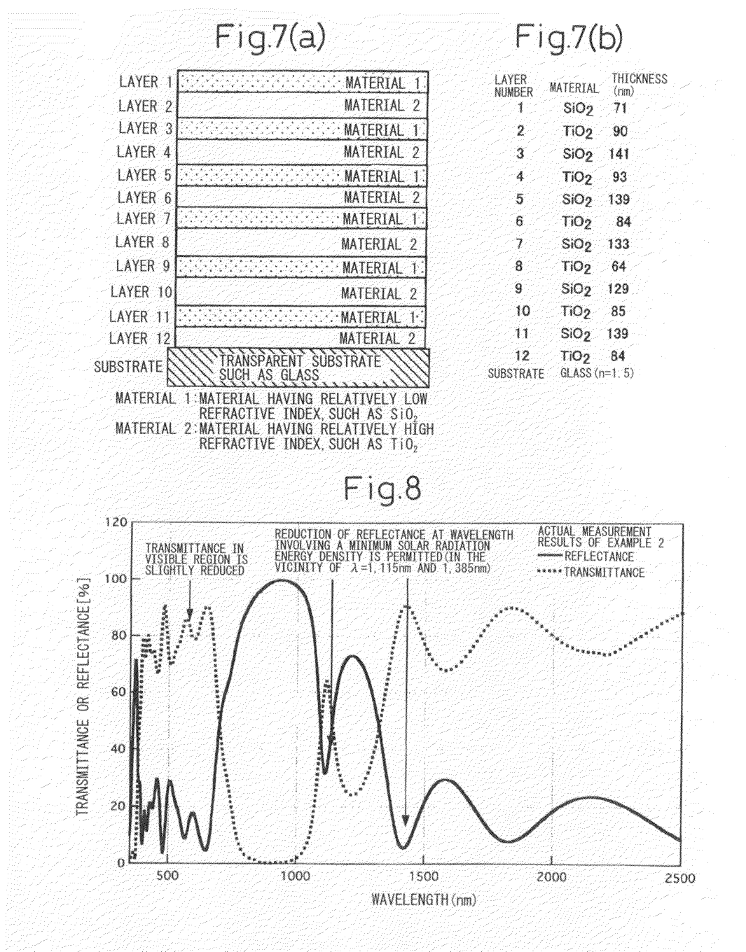

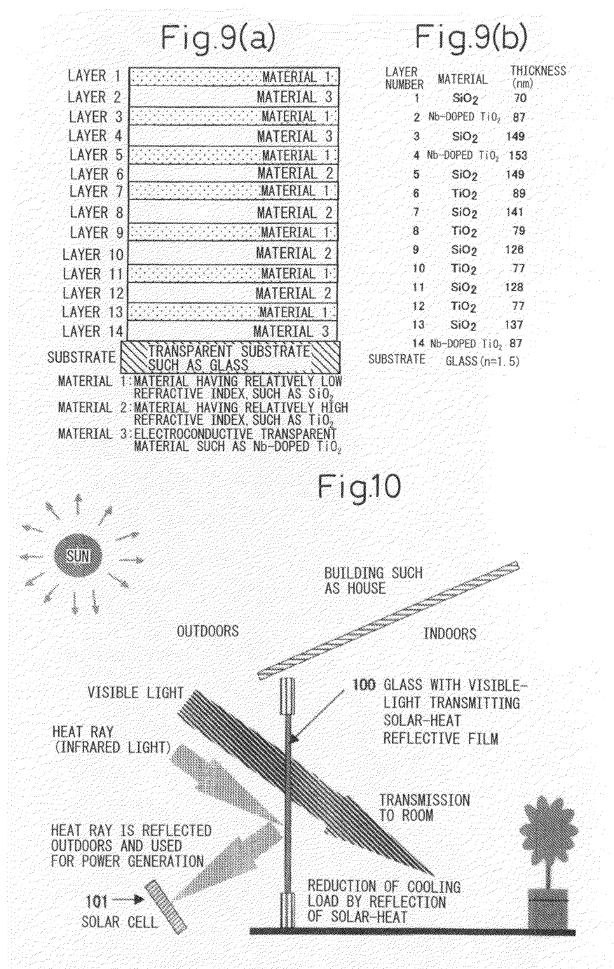

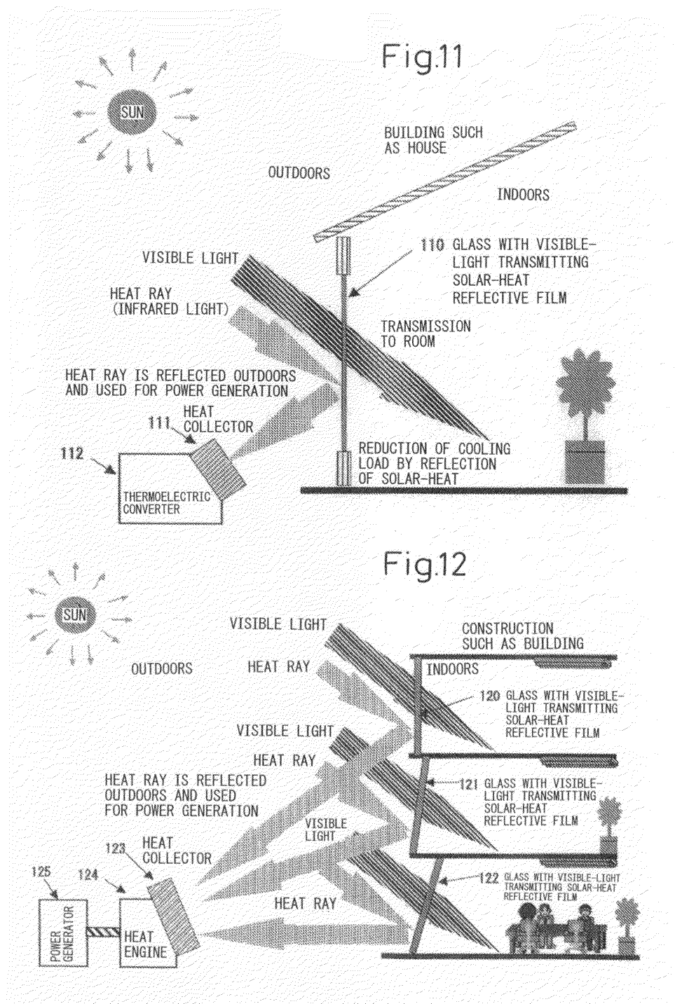

### BRIEF DESCRIPTION OF THE DRAWINGS

[FIG. 1] A view illustrating the solar radiation spectrum.

[FIG. 2] A view illustrating a relative luminosity curve of the human eye.

[FIG. 3] A conceptual view illustrating the way of thinking for the characteristic improvement (solid line) by the present invention in comparison with characteristics (dashed line) by a conventional technique. In a visible-light transmitting optical multilayer film, the reflection band for the heat ray can be hardly enlarged and therefore, by partially permitting the reduction of reflectance, the reflectance in a portion with a high heat energy density in the solar radiation is raised.

[FIGS. 4(a) and 4(b)] Views illustrating Example 1 using a 14-layer film as the visible-light transmitting solar-heat reflective film according to the present invention; FIG. 4(a) is a view roughly illustrating the constituent materials and the layer structure, and FIG. 4(b) is a view illustrating the material and thickness of each layer.

[FIG. 5] A view illustrating the transmittance and reflectance characteristics obtained in Example 1 according to the present invention.

[FIG. 6] A view illustrating the reflectance characteristics obtained in Example 1 according to the present invention, and illustrating, for comparison, both the characteristics obtained by a conventional optical multilayer film technique and the solar radiation spectrum.

[FIGS. 7(a) and 7(b)] Views illustrating Example 2 using a 12-layer film as the visible-light transmitting solar-heat reflective film according to the present invention; FIG. 7(a) is a view roughly illustrating the constituent materials and the layer structure, and FIG. 7(b) is a view illustrating the material and thickness of each layer.

[FIG. 8] A view illustrating visible-light transmission/heat reflection characteristics obtained in Example 2 according to the present invention.

[FIGS. 9(a) and 9(b)] Views illustrating Example 3 using a 14-layer film as the visible-light transmitting solar-heat reflective film according to the present invention; FIG. 9(a) is a view roughly illustrating the constituent materials and the layer structure, and FIG. 9(b) is a view illustrating the material and thickness of each layer.

[FIG. 10] A view illustrating the visible-light transmitting solar-heat reflective film of Example 4 constructed such that the heat rays reflected turns into energy supplied to a solar cell.

[FIG. 11] A view illustrating the visible-light transmitting solar-heat reflective film of Example 5 constructed such that the heat rays reflected turns into energy supplied to a thermoelectric converter.

[FIG. 12] A view illustrating the visible-light transmitting solar-heat reflective film of Example 6 constructed such that the heat rays reflected turns into energy supplied to a heat engine.

### DESCRIPTION OF NUMERICAL REFERENCES

100, 110 and 120 to 122: Glass with visible-light transmitting solar-heat reflective film

101: Solar cell

111 and 123: Heat collector

112 Thermoelectric converter

124 Heat engine

125 Power generator

### BEST MODE FOR CARRYING OUT THE INVENTION

The best mode for carrying out the visible-light transmitting solar-heat reflective film according to the present invention is described below based on Examples by referring to the drawings.

In the present invention, a visible-light transmitting solar-heat reflective film is designed to harmonize with the relative luminosity of human eye and realize efficient reflection of heat ray energy in solar radiation. First, from the relative luminosity curve of the human eye (FIG. 2), a wavelength range from 400 to 700 nm is selected as the region of visible light that should be transmitted. Next, although the ideal is to reflect all heat rays at a wavelength of 750 nm or more, as described above, it is very difficult to reflect all of these heat rays only by a multilayer film composed of a transparent material.

Accordingly, in the present invention, the reflectance in important portions is raised by permitting partial reduction of reflectance as in the characteristics shown by a solid line in FIG. 3. Judging from the solar radiation spectrum (FIG. 1), the wavelength appropriate for permitting the reduction of reflectance is set to the vicinity of wavelengths of 1,115 nm and 1,385 nm where the energy density of solar radiation is minimum due to absorption by water vapor and others in the atmosphere.

Judging from the solar radiation spectrum shown in FIG. 1, the vicinity of a wavelength of 1,115 nm is suitably from 1,080 to 1,150 nm, and similarly, the vicinity of a wavelength of 1,385 nm is suitably from 1,330 to 1450 nm. Furthermore, the heat ray reflectance is intended to raise-by also permitting some reduction of transmittance for the visible-light transmission characteristics.

The optimal characteristics for effectively reflecting heat rays in solar radiation can be determined mathematically by utilizing the Schwartz inequality. The heat rays are divided into appropriate wavelength regions and when the energy thereof is denoted by E₁, E₂, E₃, . . . Eₙ and the reflectance of the heat ray-reflective film in respective wavelength regions is denoted by R₁, R₂, R₃, . . . , Rₙ, the reflected heat ray energy is given by Pᵣ=R₁·E₁+R₂·E₂+R₃·E₃+R₄·E₄+ . . . +Rₙ·Eₙ. According to the Schwarz inequality, the relationship of the following mathematical formula (1) is established.

E₁²+E₂²+E₃²+ . . . +Eₙ²)·(R₁²+R₂²+R₃²+ . . . +Rₙ²)≧(R₁·E₁+R₂·E₂+ . . . +Rₙ·Eₙ)² (1)

Since the energy and reflectance are positive, the relationship of the following mathematical formula (2) is established.

$$\frac{{R}_{1}}{{E}_{1}} = \frac{{R}_{2}}{{E}_{2}} = \frac{{R}_{3}}{{E}_{3}} = … = \frac{{R}_{n}}{{E}_{n}} \qquad ( 3 )$$

The equality is established in the case of the following mathematical formula (3).

$${R}_{1} \cdot {E}_{1} + {R}_{2} \cdot {E}_{2} + {R}_{3} \cdot {E}_{3} + … + {R}_{n} \cdot {E}_{n} \leq \sqrt{\begin{matrix}( \begin{matrix}{E}_{1}^{2} + {E}_{2}^{2} + \\ {E}_{3}^{2} + … + {E}_{n}^{2}\end{matrix} ) \cdot \\ ( \begin{matrix}{R}_{1}^{2} + {R}_{2}^{2} + \\ {R}_{3}^{2} + … + {R}_{n}^{2}\end{matrix} )\end{matrix}} \qquad ( 2 )$$

In the above, Eⱼ (j=1, 2, 3 . . . ) is a constant because this is the energy of respective wavelength regions into which the heat ray is divided. Rⱼ (j=1, 2, 3 . . . ) is the reflectance for respective wavelength regions of the heat rays and when the sum of squares of these values is constant, the conditions for making the reflected heat ray energy Pᵣ maximum come down to formula 3).

As already described above, it is very difficult to reflect all the heat rays at a wavelength of 700 nm or more only by a multilayer film formed of a transparent material. More specifically, when preference is given to ensuring flat transmission of visible light and high reflectance at a wavelength of approximately from 750 to 1,000 nm, the reflectance for a heat ray at a wavelength of 1,050 nm or more abruptly decreases. Considering these circumstances, it is understood that with a change in the characteristics of a heat-ray reflective film, the reflected heat ray energy Pᵣ greatly fluctuates but sum of squares of Rⱼ (j=1, 2, 3 . . . ) fluctuates little.

Accordingly, an approximation that the sum of squares of reflectance for respective wavelength regions of heat rays is constant leads to a conclusion that the reflected heat-ray energy Pᵣ is maximum when the reflectance Rⱼ (j=1, 2, 3 . . . ) satisfies formula (3). In other words, under the constraint conditions used for the approximation, reflection characteristics in proportionality relation with the wavelength distribution of incident heat ray energy become optimal characteristics as a heat-ray reflective film.

The visible-light transmitting solar-heat reflective film of the present invention is based on the above-described design guide, and realizes visible-light transmission characteristics adapted to relative luminosity of the human eye as well as reflection characteristics adapted to the solar radiation spectrum at a wavelength of about 800 nm or more.

The visible-light transmitting solar-heat reflective film of the present invention utilizes the interference effect of light by an optical multilayer film and therefore, preferably has a structure where layers of two kinds of light-transparent materials greatly differing in the refractive index, i.e., one or more layers of a high refractive-index material and one or more layers of a low refractive-index material, are alternately stacked.

A light-transparent material having a refractive index of 2.0 to 2.6 and a thickness of 10 to 325 nm is used for the high refractive-index material layer, and a light-transparent material having a refractive index of 1.8 or less and a thickness of 10 to 325 nm is used for the low refractive-index material layer.

Here, the numerical ranges are set as follows for the refractive index and thickness of each of light-transparent materials used as high refractive-index material and low refractive-index material in the present invention, which are an optical material. First, the numerical range of refractive index is as follows. The visible-light transmitting solar-heat reflective film of the present invention is used by forming it on a substrate surface, and representative substrates for such film formation are a silicate- or borate-based glass and a plastic such as polycarbonate and polyethylene terephthalate. The refractive index of the glass substrate is about 1.5, and that of the plastic substrate is about 1.6.

Meanwhile, the following two points are taken into consideration in selecting the materials for use in the present invention. First, in order to reflect only the heat ray by utilizing optical reflection as in the present invention, it is preferred to combine light-transparent materials greatly differing in the refractive index. Secondly, as regards the material for one member of the optical materials combined, it is advantageous for raising the optical periodicity of a multilayer structure and obtaining excellent characteristics to select a material having a refractive index equivalent to that of the substrate.

In respect of the lower refractive index material, the minimum value of refractive index of the material is 1.0 that can be realized only by vacuum, and a refractive index smaller than 1.4 cannot be easily obtained by actual solid material for optical use. Considering the refractive index equal to that of the substrate, the refractive index of the material on the low refractive index side is preferably around 1.5.

As for the higher refractive index material, use of titanium oxide, tin oxide, zinc oxide, indium oxide or the like, which are representative as a dielectric material having a refractive index of 2.0 or more, is advantageous. Some special materials such as gallium arsenic have a refractive index exceeding 3.0 but are not practical. Considering the combination of the above-described substrate with practical thin-film materials, the refractive index on the low refractive-index side is 1.8 or less, and the refractive index on the high refractive-index side is approximately from 2.0 to 2.6.

Next, the thickness of each layer constituting a multilayer film needs to be a thickness effective in utilizing interference of light. To take a specific wavelength as an example, it is known that light can be weakened by synthesizing a light wave whose phase is shifted by ½ wavelength. In this way, a value of approximately from 1/40 to ½ the light wavelength is required as the thickness of each layer so as to produce a phase difference of light and at the same time, control the interference characteristics. In the present invention, since the range from visible light to heat rays at a wavelength of about 1,400 nm is controlled by placing the boundaries at a wavelength of 400 nm and a wavelength of 750 nm, the thickness of each layer is suitably from 10 to 325 nm.

As for the visible-light transmission characteristics, the required transmittance varies greatly, i.e., for example, smoked glass is used depending on usage, but for use as a windshield of vehicles, etc., an average transmittance of at least 70% or more is necessary. In order to use the film like a normal windowpane, the lower limit of the average transmittance is suitably about 60%, and although the upper limit is theoretically 100%, a reflectance of about 95% is the limit of production.

The most principal portion of the heat ray energy contained in solar radiation is carried over by light around a wavelength of approximately from 800 to 1,050 nm. Accordingly, in order to effectively shield heat from solar radiation, a reflectance of 60% or more on average at a wavelength of 800 to 1,040 nm is necessary, but for obtaining a more distinct effect, a reflectance of 80% or more is preferred. The upper limit is theoretically 100%, but about 90% is practically a limit allowing for production.

For the heat ray at 1,150 to 1,300 nm on the long wavelength side where the energy density is a little reduced, a reflectance of at least 40% or more on average is necessary so as to raise the heat-shielding effect, and with a reflectance of 50% or more, the effect is more distinctly obtained. The upper limit is theoretically 100%, but a reflectance of about 70% is the limit of production.

On the wavelength side longer than a wavelength of 1,300 nm, the energy density is further reduced and the weight as solar heat decreases. In view of such characteristics of solar radiation, the heat reflection at a wavelength of 1,300 nm or more is dealt with as a property not governing the heat-shielding effect, but as a property acting subsidiarily.

The electromagnetic-wave transmission characteristics are designed, assuming that cellular phone and wireless LAN are the main application. For such wireless communication, electromagnetic waves in the frequency range from hundreds of MHz to several GHz need to be transmitted. According to the theory of plasma reflection, an insulating material is supposed to be advantageous for allowing transmission of an electromagnetic wave. In the present invention, an insulating material such as silicon oxide, titanium oxide and tantalum oxide is used with an attempt to realize both transmission of electromagnetic waves in the range above and visible-light transmitting solar-heat reflection. In order to ensure stable wireless communication through radio waves, an electromagnetic-wave-energy transmittance of 80% or more is considered suitable. Accordingly, the target value of attenuation is set at 2 dB or less obtained by converting the value above to decibel.

Incidentally, for the production of a multilayer film in the visible-light transmitting solar-heat reflective film of the present invention, known film-forming techniques such as sputtering, vacuum deposition, electron beam evaporation and a CVD, as well on laser deposition, a coating method and a spraying method are utilized.

### Example 1

FIG. 4 illustrates Example 1 of the visible-light transmitting solar-heat reflective film according to the present invention. FIG. 4(a) illustrates the layer structure of the visible-light transmitting solar-heat reflective film of Example 1, and FIG. 4(b) illustrates the material and thickness of each layer constituting the visible-light transmitting solar-heat reflective film. In Example 1, as shown in FIG. 4(a), a layer of second material and a layer of first material were alternately stacked in sequence from the bottom by repeating the stacking operation 7 times to form an optical multilayer film consisting of 14 layers.

The first material was a high refractive index material and titanium oxide (TiO₂) was used, whereas the second material was a low refractive-index material and silica (SiO₂) was used. Accordingly, the visible-light transmitting solar-heat reflective film of Example 1 was composed of an optical multilayer where a stack “SiO₂/TiO₂” is repeated 7 times from the bottom, and was provided on a glass substrate.

FIG. 5 illustrates the results of actual measurement of the visible-light transmitting solar-heat reflective film of Example 1 produced experimentally by using a sputtering method. As shown in FIG. 5, the transmission property in the visible light region was somewhat reduced, but a high reflectance exceeding 90% was achieved at a wavelength of 850 nm representative of the heat ray having a high energy density, while keeping a high visible-light transmittance of 82% on average. In this way, it was revealed that both high visible-light transmission and effective solar-heat reflection can be realized by the present invention.

FIG. 6 illustrates the reflection characteristics in comparison with the characteristics of a 14-layer film according to a conventional invention and the solar radiation energy spectrum. The correlation between the solar radiant spectrum and the reflectance characteristics was greatly improved over a wide wavelength range up to 2,400 nm as compared with the conventional technique. By calculating the energy reflectance for solar heat from the obtained reflectance characteristics, it was roughly estimated that in the heat ray region from a wavelength of 750 nm to a wavelength of 2,400 nm, about 60% of solar radiation energy is reflected.

In the conventional technique, the energy transmittance was as high as about 90% in the visible light region, but in the heat ray region from a wavelength of 750 nm to a wavelength of 2,400 nm, the solar radiation energy reflectance was roughly estimated at about 50%. In this way, the solar-heat reflecting performance of the present invention was roughly' estimated at about 1.2 times that of the conventional technique.

Using a sample obtained by forming the visible-light transmitting solar-heat reflective film of Example 1 on a 1.5 mm-thick glass substrate, the electromagnetic wave transmission was confirmed. The change of radio wave intensity when the window of a shield box having a window of 15 cm×3 cm was opened and when the window was covered with the sample was analyzed by a spectrum analyzer. The results of measurement performed at frequencies of 800 MHz and 2.4 GHz by placing a receiving antenna in the shield box and placing a transmitting antenna in the distance out of the shield box are shown in Table 1. The attenuation of electromagnetic wave at these frequencies was less than 1 dB and is very low, and it was presumed that electromagnetic waves in a wider frequency range are transmitted. Furthermore, when a pair of wireless LAN antennas was placed in this shield box, the wireless LAN was confirmed to be operable without trouble.

TABLE 1
Attenuation of Electromagnetic Wave
due to Transmission Through Sample

Frequency of Electromagnetic Wave

| | 800 MHz | 2.4 GHz |
|---|---|---|
| Attenuation | 0.2 dB | 0.3 dB |

In Example 1 having a 14-layer construction, thanks to a relatively large number of layers, steep transition characteristics between transmission and reflection were realized, but according to the present invention, similar characteristics can be realized with a smaller number of layers than 14 layers.

### Example 2

In Example 2 shown in FIG. 7, an optical multilayer film having a structure of a stack “SiO₂/TiO₂” being repeated 6 times from the bottom was provided on a glass substrate. FIG. 8 illustrates the results of actual measurement of the visible-light transmitting solar-heat reflective film of Example 2 produced experimentally by using a sputtering method. As shown in FIG. 8, a high reflectance of about 85% was achieved at a wavelength of 800 nm representative of the heat ray having a high energy density, while keeping a high visible-light transmittance of 80% on average. Furthermore, by calculating the energy reflectance for solar heat from the reflectance characteristics shown in FIG. 8, it was roughly estimated that in the heat ray region from a wavelength of 700 nm to a wavelength of 2,400 nm, about 60% of solar heat energy was reflected.

In Examples 1 and 2, the basic structure was repetition of “SiO₂/TiO₂”, but the reflection characteristics on the long wavelength side can be improved by using a material having both light transparency and electrical conductivity, such as ITO (In₂O₃—SnO₂) and Nb-doped TiO₂. Enhancement of reflectance in the long wavelength region exceeding 3,000 nm can contribute to reduction of heating load for air heating in winter by virtue of reflection of heat radiation in a room.

The principle of heat ray reflection by the introduction of an electroconductive material transparent in the visible light region is plasma reflection, and it is theoretically suggested that introduction of a transparent electroconductive material having a carrier concentration of about 1×10²⁷/m³ is effective for heat ray reflection at a wavelength of about 2,000 nm or more. Such a carrier concentration is known to be obtainable by a transparent electroconductive material such as ITO and Nb-doped TiO₂.

### Example 3

As Example 3, FIG. 9 illustrates an example of the visible-light transmitting solar-heat reflective film according to the present invention comprising Nb-doped TiO₂, TiO₂ and SiO₂.

### Example 4

As Example 4, FIG. 10 illustrates an example of the visible-light transmitting solar-heat reflective film, where a heat ray reflected by glass 100 with a visible-light transmitting solar-heat reflective film is irradiated on a solar cell 101 and electric power is thereby generated. According to the present invention, a heat ray on the longer wavelength side than a wavelength of about 750 nm can be separated, so that not only visible light can be utilized for natural indoor lighting but also a heat ray separated from solar radiation can be utilized for solar power generation.

### Example 5

As Example 5, FIG. 11 illustrates an example of the visible-light transmitting solar-heat reflective film, where solar heat reflected by glass 110 with a visible-light transmitting solar-heat reflective film is supplied as energy to a thermoelectric converter 112 through a heat collector 111. In Example 4 where light energy is irradiated on a solar cell, the wavelength of light usable for power generation is restricted by a semiconductor that is a material of the solar cell. For example, light usable for power generation of a silicon solar cell is light at a wavelength of about 1,100 nm or less, but this restriction can be advantageously removed when a thermoelectric converter is used.

### Example 6

As Example 6, FIG. 12 illustrates an example of the visible-light transmitting solar-heat reflective film, where solar radiant heat reflected by glasses 120 to 122 with a visible-light transmitting solar-heat reflective film is supplied as energy to a heat engine 124 through a heat collector 123 and a power generator 125 is thereby rotated to generate electric power. This example is constructed such that by using a plurality of glasses 120 to 122 with a visible-light transmitting solar-heat reflective film and concentrating heat rays contained in solar radiation and reflected on these glasses, effective heat collection can be performed. Examples of the heat engine which can be used include a steam turbine, a gas turbine and a stirling engine.

### INDUSTRIAL APPLICABILITY

The visible-light transmitting solar-heat reflective film according to the present invention, when applied to a window of buildings, vehicles, houses and the like, can reflect an infrared ray having a strong heat effect while ensuring natural lighting from solar radiation, and therefore its utility value for energy saving is high. In summer season when air conditioning is required, the cooling load can be reduced by the reflection of solar heat, whereas in winter season when air heating is required, the heating load can be reduced by reflecting heat radiation in a room.

Furthermore, the product of the present invention comprising a visible-light transmitting solar-heat reflective film and a solar power generator satisfies all of the utilization of visible light for natural lighting, the reflection of heat ray for reducing the heat load, and the function of generating electric power by heat ray and therefore, its utility value is high in view of energy saving of buildings, vehicles, houses and the like.

In addition, the product of the present invention is assured of all of high visible light transmittance, steep transition characteristics and electromagnetic wave transmitting property, and therefore is most suitable for a vehicle windshield, an observation window and the like.

1. A visible-light transmitting solar-heat reflective film formed on a light-transparent substrate, comprising a multilayer film containing one or more layers of a high refractive index material having a refractive index of 2.0 to 2.6 and a thickness of 10 to 325 nm and one or more layers of a low refractive index material having a refractive index of 1.8 or less and a thickness of 10 to 325 nm, wherein the average transmittance for light at a wavelength of 400 to 700 nm is 60% or more; and the reflectance in the vicinity of wavelengths of 1,115 nm and 1,385 nm, where the energy density on the earth's surface becomes minimum in the heat rays contained in solar radiation due to absorption by water vapor and others in the atmosphere, is sacrificed so as to raise the average reflectance for heat rays at a wavelength of 800 to 1,040 nm involving a relatively high energy density to 80% or more and raise the average reflectance for heat rays at a wavelength of 1,150 to 1,300 nm to 50% or more.

2. The visible-light transmitting solar-heat reflective film as claimed in claim 1, wherein said light-transparent substrate is a glass or a plastic.

3. The visible-light transmitting solar-heat reflective film as claimed in claim 1, wherein said high refractive index material layer is formed of a material comprising, as the main component, a metal oxide composed of one member or two or more members selected from the group consisting of titanium, indium, tin, zinc, cerium, bismuth, zirconium, niobium and tantalum.

4. The visible-light transmitting solar-heat reflective film as claimed in claim 1, wherein said low refractive index material is composed of a material comprising, as the main component, a fluoride of calcium, barium, lithium or magnesium, or silica.

5. The visible-light transmitting solar-heat reflective film as claimed in claim 1, wherein said reflected heat ray is irradiated on a solar cell to generate electric power.

6. The visible-light transmitting solar-heat reflective film as claimed in claim 1, wherein said reflected heat ray is supplied to a thermoelectric converter through a heat collector.

7. The visible-light transmitting solar-heat reflective film as claimed in claim 1, wherein said reflected heat ray is supplied as energy to a heat engine through a heat collector.

8. A visible-light transmitting solar-heat reflective film formed on a light-transparent substrate, comprising a multilayer film containing one or more layers of a high refractive index material having a refractive index of 2.0 to 2.6 and a thickness of 10 to 325 nm and one or more layers of a low refractive index material having a refractive index of 1.8 or less and a thickness of 10 to 325 rim, wherein the attenuation for an electromagnetic wave at a wavelength of 800 MHz to 2.4 GHz is 2 dB or less; the average transmittance for light at a wavelength of 400 to 700 rim is 60% or more; and the reflectance in the vicinity of wavelengths of 1,115 nm and 1,385 nm, where the energy density on the earth's surface is minimum in the heat rays contained in solar radiation due to absorption by water vapor and others in the atmosphere, is sacrificed so as to raise the average reflectance for heat rays at a wavelength of 800 to 1,040 nm involving a relatively high energy density to 80% or more and raise the average reflectance for heat rays at a wavelength of 1,150 to 1,300 rim to 50% or more.
